(19) United States
(12) Patent Application Publication
(10) Pub. No.: US 2020/0053882 A1
(43) Pub. Date: Feb. 13, 2020

(54) NETWORK DEVICES AND NETWORK ELEMENTS WITH BELLY TO BELLY SMALL FORMAT PLUGGABLE MODULES

(71) Applicant: Arista Networks, Inc., Santa Clara, CA (US)

(72) Inventor: Xiaoping Han, Milpitas, CA (US)

(21) Appl. No.: 16/101,326

(22) Filed: Aug. 10, 2018

(51) Int. Cl. H05K 3/30; H01R 12/00; H01R 12/58

(52) U.S. Cl. CPC H05K 3/306; H05K 2201/10189; H01R 12/58; H01R 9/092

(57) ABSTRACT

In one embodiment, an apparatus is provided. The apparatus includes a printed circuit board (PCB) that includes a set of vias through the PCB. The apparatus also includes a first small format pluggable (SFP) module coupled to a first surface of the PCB. The first SFP module includes a first set of pins configured to interface with a first subset of the set of vias. The first set of pins has a first pin layout. The apparatus further includes a second SFP module coupled to a second surface of the PCB. The second SFP module includes a second set of pins configured to interface with a second subset of the set of vias. The second set of pins has a second pin layout. A first pin of the first set of pins interfaces with a first via. A second pin of the second set of pins interfaces with the first via. The first subset and the second subset include the first via.

### BACKGROUND

Network elements, such as switches, routers, hubs, servers (e.g., rackmount servers) may include a chassis with one or more slots. Network devices (e.g., network components), such as line cards, control cards, etc., may be inserted into the slots. The network elements may perform various functions that may be used during the operation of the network element. For example, a switch may include multiple line cards that are inserted into multiple slots in the chassis of the switch. Each of the line cards may be coupled to other network elements (e.g., to ports of other switches), to other line cards within the same network element, and/or to different networks. Each network device may be coupled to a fabric of the network element via one or more connectors inside the chassis of the network element. For example, each network device may include a connector that may be coupled to another connector on a fabric or a mid-plane of the network element. The fabric may allow the different network devices to communicate data with each other. For example, the fabric may allow data received from a first port of a first line card to be communicated (e.g., routed) to a second port of a second line card. Each line card may include network modules (e.g., fiber optic modules, small form-factor pluggable (SFP) modules, etc.) that may be coupled to a printed circuit board (PCB) of a line card.

### SUMMARY

In some implementations, a network device is provided. The network device includes a printed circuit board (PCB) that includes a set of vias through the PCB. The network device also includes a first small format pluggable (SFP) module coupled to a first surface of the PCB. The first SFP module includes a first set of pins configured to interface with a first subset of the set of vias. The first set of pins has a first pin layout. The network device further includes a second SFP module coupled to a second surface of the PCB. The second SFP module includes a second set of pins configured to interface with a second subset of the set of vias. The second set of pins has a second pin layout. A first pin of the first set of pins interfaces with a first via. A second pin of the second set of pins interfaces with the first via. The first subset and the second subset include the first via.

In some implementations, a network element is provided. The network element includes a chassis configured to house a plurality of network devices. The network element also includes a network device housed within the chassis. The network device includes a printed circuit board (PCB) that includes a set of vias through the PCB. The network device also includes a first small format pluggable (SFP) module coupled to a first surface of the PCB. The first SFP module includes a first set of pins configured to interface with a first subset of the set of vias. The first set of pins has a first pin layout. The network device further includes a second SFP module coupled to a second surface of the PCB. The second SFP module includes a second set of pins configured to interface with a second subset of the set of vias. The second set of pins has a second pin layout. A first pin of the first set of pins interfaces with a first via. A second pin of the second set of pins interfaces with the first via. The first subset and the second subset include the first via.

In some implementations, a method is provided. The method includes obtaining a printed circuit board (PCB) that includes a set of vias through the PCB. The method also includes obtaining a first small format pluggable (SFP) module. The first SFP module includes a first set of pins configured to interface with a first subset of the set of vias. The first set of pins has a first pin layout. The method further includes obtaining a second SFP module. The second SFP module includes a second set of pins configured to interface with a second subset of the set of vias. The second set of pins has a second pin layout. The method further includes coupling the first SFP module to a first surface of the PCB. The method further includes coupling the second SFP module to a second surface of the PCB. A first pin of the first set of pins interfaces with a first via. A second pin of the second set of pins interfaces with the first via. The first subset and the second subset comprise the first via.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1A is a perspective view of a printed circuit board with both faces receiving connectors in groups.

FIG. 1B is a perspective view of a variation of the printed circuit board and the groups of connectors of FIG. 1A.

FIG. 2 is a cross-section view of the printed circuit board, showing connector pins inserted into a via.

FIG. 3 is a cross-section view of the printed circuit board, showing connector pins inserted into dual-diameter vias, which support closer spacing of vias.

FIG. 4 is a cross-section view of the printed circuit board, showing back drilled dual-diameter vias, with plating removed from a portion of the via so as to reduce crosstalk with neighboring vias, especially those oriented in an opposite direction.

FIG. 5A is a top projected view that depicts a problem with ground vias colliding with vias for signal pins, creating a short-circuit.

FIG. 5B is a top projected view that depicts a solution to the problem of FIG. 5A, with a solitary or singular ground via adjacent to two signal vias.

FIG. 6 depicts the via arrangement of FIG. 5B in a lateral projected cross-section view, showing ground return paths through the solitary or singular ground via for two signals with pins on opposed faces of the printed circuit board.

FIG. 7A depicts offset back drilling in the printed circuit board.

FIG. 7B is a cross-section view of the printed circuit board, showing a staggered via produced by the offset back drilling of FIG. 7A.

FIG. 7C is a cross-section view of the printed circuit board, showing a variation of the staggered via of FIG. 7B.

FIG. 7D is a cross-section view of the printed circuit board, showing a further variation of the staggered via of FIG. 7B.

FIG. 8 is a perspective view of a quad small form factor pluggable (QSFP) connector, suitable for use in embodiments of the present disclosure, with the connector pins shown.

FIG. 9 is a flow diagram of a method for making a printed circuit board, which can produce the embodiments shown in FIGS. 4 and 6 and variations thereof.

FIG. 10 illustrates a perspective view (e.g., an isometric view) of a network device 1000 in accordance with one or more embodiments of the present disclosure.

FIG. 11 is a side view of a network device 1000 in accordance with one or more embodiments of the present disclosure.

FIG. 12 is a diagram illustrating example pin layouts 1250 and 1260 for SFP modules 1010 and 1020 in accordance with one or more embodiments of the present disclosure.

FIG. 13 is an overhead view of a portion 1300 of printed circuit board (PCB) 1010 in accordance with one or more embodiments of the present disclosure.

FIG. 14 is a diagram illustrating a combined pin layout 1400 in accordance with one or more embodiments of the present disclosure.

FIG. 15 is a diagram illustrating example pin layouts 1550 and 1560 for SFP modules 1010 and 1020 in accordance with one or more embodiments of the present disclosure.

FIG. 16 is a diagram illustrating a combined pin layout 1600 in accordance with one or more embodiments of the present disclosure.

FIG. 17 is a perspective view of a network element 900 in accordance with one or more embodiments of the present disclosure.

FIG. 18 is a flow diagram of a method of assembling a network device in accordance with one or more embodiments of the present disclosure.

### DETAILED DESCRIPTION

As discussed above, network elements may include a chassis with one or more slots. Network devices, such as line cards, may be inserted into the slots. The size of the chassis may limit the number of slots and thus, the number of network devices (e.g., line cards) that may be used in a network element. Network requirements for users are constantly increasing. For example, users may want to transmit and/or receive more data, may want to transmit and/or receive data at faster speeds, may want to connect/interconnect more networks, etc. As network requirements increase, it may be useful to increase the capabilities of a network element without increasing the size of the chassis and/or without increasing the number of slots in a chassis. In some embodiments, the capabilities and/or capacity of a network element may be increased by connecting modules of a network device (e.g., a line card) in a belly-to-belly fashion. This may increase the capabilities and/or capacity of the line card without increasing the number of slots in the chassis of the network element. Each line card may include network modules (e.g., fiber optic modules, small form-factor pluggable (SFP) modules, etc.) that may be coupled to a printed circuit board (PCB) of a line card. The network modules may be coupled to the printed circuit boards via connectors which may include connector pins.

Connectors with high densities of pins, mated to printed circuit boards, are well- known in many types of electronic devices, including network devices. When it is desired to increase the number of connectors mounting to a printed circuit board, for example to increase the number of channels in a network device, problems arise. Board size could increase, if all of the connectors are on the same side of the printed circuit board, but the board will no longer fit the desired form factor for packaging and rack mounting. Signal travel could be over differing distances and necessitate buffering, amplification or other circuitry to compensate for circuit path differences and signal quality differences. Solving these problems by mounting connectors on both faces of the printed circuit board for more symmetric signal trace lengths may introduce more problems. Connector pins could collide and bend, some vias and via pads could electrically short to other vias. Signal crosstalk and ground noise could increase because of newly introduced spacing problems and signal couplings. High-speed signals could have signal integrity problems that need different solutions from what works for low-speed signals. Various pins, be they signal, power supply or ground, could be misaligned from one face of the printed circuit board to the other face, especially if the connectors were not originally designed for mounting on both sides of a printed circuit board (called a Belly-to-Belly mount). Hypothetically ideal solutions might not be practical with existing printed circuit board manufacturing techniques. And, redesigning the connectors and manufacturing all of the variations of the connectors that currently exist within a connector family that conforms to an existing standard is time-consuming and costly, perhaps prohibitively so for a product or product line. Given the challenges described above, there is a need in the art for a solution.

In addition, various embodiments of printed circuit boards, vias, drilling and other printed circuit board manufacturing techniques disclosed herein can be used in various combinations for making and using printed circuit boards that can mount press-fit connectors on both faces of the printed circuit board. Each embodiment or variation thereof solves one or more problems and is therefore applicable to solving similar problems in other connector and printed circuit board arrangements, and is not limited to the specific connector shapes and printed circuit boards depicted herein. The drawings are representative and suggestive of geometries in various embodiments but are not to scale. Descriptions herein should be interpreted as gravity independent, in that a printed circuit board and connectors may be mounted in various orientations and a description of “top”, “bottom”, “upper”, “lower”, etc., is given as relative to a drawing, not absolute as to an orientation of a component in a manufacturing or operating environment. Variations of the vias with a greater number or lesser number of sections, and different shapes for the sections, are readily devised in keeping with the teachings herein.

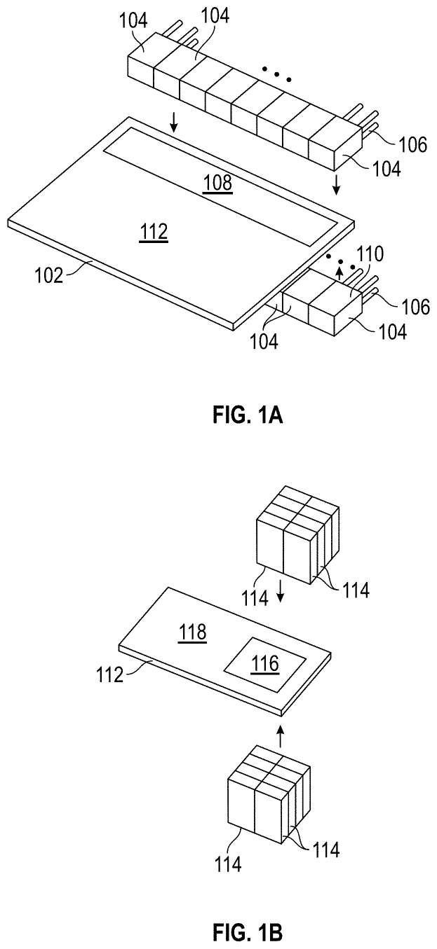

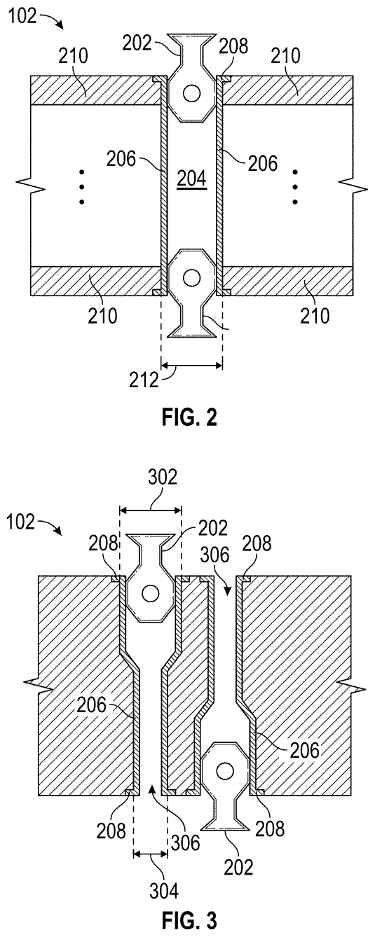

FIG. 1A is a perspective view of a printed circuit board 102 with both faces receiving connectors 104 in groups. This can be called a belly-to-belly arrangement of connectors 104. In this depiction, the connectors 104 are arranged eight in a row in each group. One group of connectors 104 is shown above and descending towards one face of the printed circuit board 102, the other group is shown below and ascending towards an opposing face of the printed circuit board 102. Cables 106 attach to the connectors 104, for routing signals through the cables 106, through the connectors 104, and to and from the circuit traces in the printed circuit board 102. In one embodiment, each connector 104 has four cables, corresponding to four channels for a network device, so that each group of eight connectors 104 has 32 channels, and the printed circuit board 102 has 64 channels. Power and ground connections are also achieved through the cables 106, and connectors 104, to the printed circuit board 102. Each connector 104 has a pin face 110, with a plurality of pins (not shown in FIG. 1A, but see FIGS. 2-4, 6, 7B and 8), that connects to a pin receiving area 108 of the face of the printed circuit board 102 to which that connector 104 mounts. Each of the two opposed faces of the printed circuit board 102 has a pin receiving area 108, details of which are shown in FIGS. 2-8 as problem solutions. A circuitry area 112 has integrated circuits, or, on an unpopulated board, is available for integrated circuits, although various embodiments of the printed circuit board 102 are further applicable to signal routing boards that do not have integrated circuits thereupon.

FIG. 1B is a perspective view of a variation of the printed circuit board 102 and the groups of connectors 104 of FIG. 1A. Here, the connectors 114 are organized as a pair of 2×4 groups of eight connectors 114, for a total of eight connectors 114 above and eight connectors 114 below the printed circuit board 112. The pin receiving area 116 of each face of the printed circuit board 112 is arranged accordingly. A circuitry area 118 has or is available for integrated circuits 112. Other printed circuit boards and arrangements and numbers of connectors are readily devised in keeping with the teachings herein.

FIG. 2 is a cross-section view of the printed circuit board 102, showing connector pins 202 inserted into a via 204. The particular connector pins 202 depicted are press-fit pins, which have void (depicted as the central oval) and collapse slightly upon insertion into a via 204, but other types of pins could be used. Generally, vias 204 that receive pins 202 are dimensioned to grip the pins 202, for good mechanical and electrical contact, and to retain the connector. Plating 206 on the wall(s) of the via 204 provide electrical connectivity to the pins 202 and ground planes 210, or power planes or signal traces, etc., depending upon what electrical connections and definitions the pins 202 have. Standard printed circuit board manufacturing techniques such as drilling with drill bit(s) or laser(s), etching, lamination, and plating are used to produce the via 204, which extends to both faces of the printed circuit board 102 and is plated all the way through from one face to the other. Width 212 of the via is constant and uniform throughout the via 204, and should be dimensioned to receive the pins 202. This embodiment is suitable for pins 202 that are in mutual alignment as inserted through opposed faces of the printed circuit board 102. This has applicability for ground pins (shown), and also power pins and signal pins in various embodiments.

FIG. 3 is a cross-section view of the printed circuit board 102, showing connector pins 202 inserted into dual-diameter vias 306, which support closer spacing of vias. For comparison, constant-width vias 204 such as depicted in FIG. 2 have a greater minimum spacing requirement, for a given pin 202 size, than dual-diameter vias 306 oriented in opposing directions as depicted in FIG. 3. This is because the narrower portion of the dual-diameter via 306 has a smaller pad 208 than does the wider portion of the dual-diameter via 306, so, for a minimum pad spacing dimension, the opposed dual-diameter vias 306 are spaced closer together than the constant-width vias 204.

The dual-diameter via 306 can be formed by making a hole of a first, smaller diameter 304 (e.g., with a smaller drill bit or finer laser beam) all the way through the printed circuit board 102, then back drilling to a larger diameter 302 (e.g., with a larger drill bit or laser beam), to a controlled depth. This is followed by plating the entire via 306, so that there is plating 206 on the wall(s) of the dual-diameter via 306, from one face of the printed circuit board 102 to the opposing face. Circuit trace(s) in various layers in the printed circuit board 102 (even including a top or bottom layer) are readily made to the plating 206 at the thicker or thinner or transitioning portions of the dual-diameter via 306, or even at a surface of the printed circuit board 102. The larger diameter 302 should be dimensioned to receive the pin 202. The smaller diameter 304 could be dimensioned to be a minimum in accordance with printed circuit board manufacturing capabilities. In some embodiments, the dual-diameter via 306 is suitable for lower speed signals, e.g., of 1 MHz or below. Because of the closer spacing afforded by the dual-diameter vias 306, as compared to single-diameter vias (see FIG. 2), the dual-diameter vias 306 can be used to solve crowding or spacing problems arising from using connectors 104 on both faces of a printed circuit board 102.

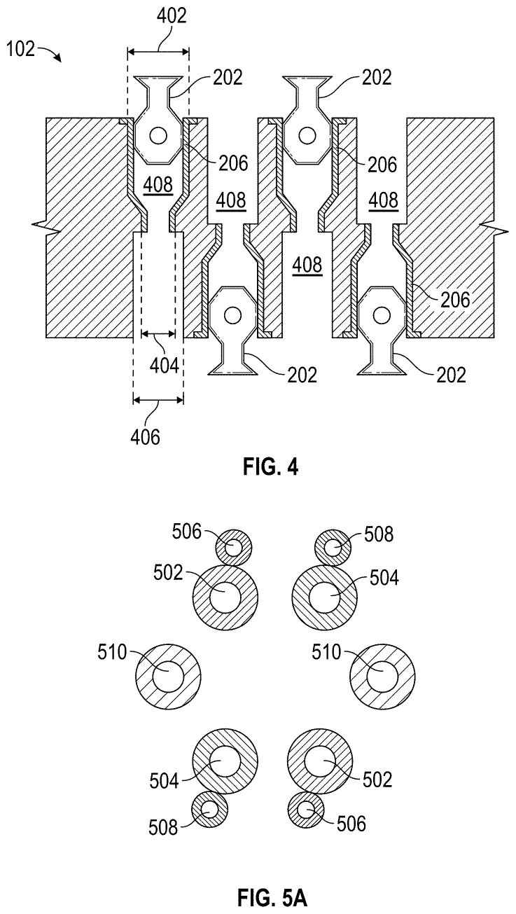

FIG. 4 is a cross-section view of the printed circuit board 102, showing back drilled dual-diameter vias 408, with plating 206 removed from a portion of the via so as to reduce crosstalk with neighboring vias, especially those oriented in an opposite direction. Each back drilled dual-diameter via 408 can be produced by starting with a dual-diameter via 306 as shown in FIG. 3, e.g., produced from a first hole by a first back drilling followed by plating. This is followed by a second back drilling to a controlled depth from the face of the printed circuit board 102 opposed to the face from which the pin 202 is received into that via 408. A second back drilling removes the plating 206 from the first back drilled portion of the via 408, to the controlled depth of the second back drilling. This results in a via 408 that has three diameters. A first section having a wider diameter 402 is produced by the first back drilling and dimensioned to receive the pin 202 through a face of the printed circuit board 102. A second, internal section having a narrower diameter 404 is produced by the first drilling, prior to any of the back drilling, and can be a minimum manufacturing diameter or other relatively narrow diameter. Plating 206 is added after the drillings produce the first and second diameters 402, 404. Preferably, a narrower second diameter 404 for that corresponding necked-down second section of the via 408 results in less total area of plating 604 in that second section of the via 408 and less radiation of electromagnetic energy arising from signal activity, also less antenna size susceptible to crosstalk. A third section having a third diameter 406 open to the opposing face of the printed circuit board 102 is produced by the second back drilling, which removes the plating. It is preferred that the third diameter 406 be slightly greater than the second diameter 404, and less than the first diameter 402, so as not to limit via spacing, but the third diameter 406 could be greater than or equal to the first diameter 402 in further embodiments.

Signal connections can be made from the via 408 to one or more conducting layers in the printed circuit board 102. For example, signal traces could be on a surface layer connected to a pad 208 of the via 408, or on an internal layer (see, e.g., FIG. 2). A signal trace on an internal layer could connect to the via 408 at the plating 206, i.e., anywhere along the thicker or thinner sections of the via 408 that have plating 206, wherever a signal layer is defined in the printed circuit board 102. Generally, one of these vias 408 connects to a signal trace on a layer on the same half of the printed circuit board 102, relative to the depth of the via 408, as the face of the printed circuit board 102 through which that via receives the connector pin 202. In other words, a via 408 that receives a signal pin 202 through an upper face of the printed circuit board 102 generally connects that signal to a signal trace on the upper half of the thickness of the printed circuit board 102. This is because the plating 206 has been removed from the lower half or other portion of the via 408, and plating 206 extends halfway through or in any case less than all the way through the printed circuit board 102 from the upper face. A via 408 that receives a signal pin 202 through a lower face of the printed circuit board generally connects that signal to a signal trace on the lower half of the thickness of the printed circuit board 102. This is because the plating 206 has been removed from the upper half or other portion of the via 408 and extends halfway through or in any case less than all the way through the printed circuit board 102 from the lower face.

When a back drilled dual-diameter via 408 is arranged adjacent to another back drilled dual-diameter via 108 in an opposed orientation, so that the first via 408 receives a pin 202 through one face of the printed circuit board 102 and the second via 408 receives another pin 202 through the opposed face of the printed circuit board 102, signal crosstalk between the two vias 408 is minimized This compares favorably with crosstalk that would have occurred if the plating in both vias 408 had been left intact, as is the case shown in FIG. 3. Thus, embodiments depicted in FIG. 4 are suitable for higher speed signals, e.g., in the gigahertz range and up. Because of both spacing advantages and advantages in crosstalk reduction, the back drilled dual-diameter vias 408 can be used to solve both spacing and crowding problems, and crosstalk problems arising from having signals entering or exiting both faces of a printed circuit board 102 to connectors 104. In order to minimize signal crosstalk, it is preferred that the second back drilling, the one that removes the plating and produces the third diameter 406, have controlled depth greater than or equal to the first controlled depth, greater than or equal to the extent of the plating 206 in a neighboring, oppositely oriented via, or greater than or equal to halfway through the printed circuit board 102. However, lesser amounts of plating removal due to a shallower second controlled depth will reduce crosstalk, too.

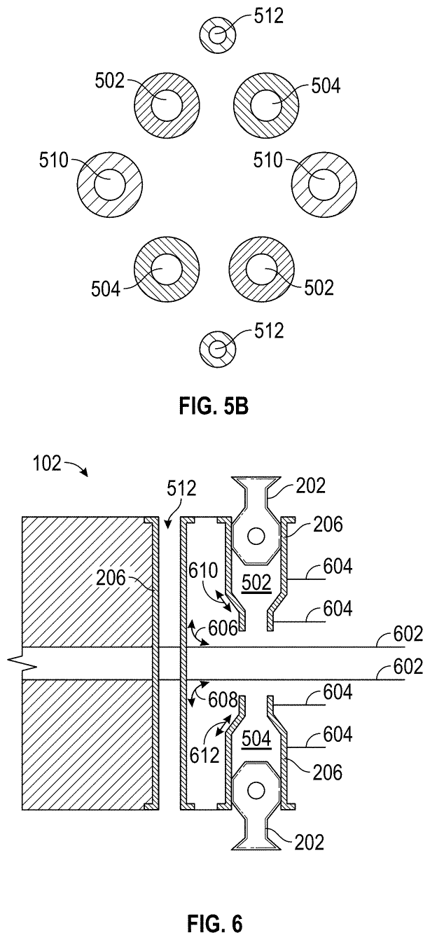

FIG. 5A is a top projected view that depicts a problem on a printed circuit board design with ground vias 506 colliding with vias 502, 504 for signal pins, creating a short-circuit. For example, such a problem could arise when a connector 104 was originally designed for use on one face of a printed circuit board, and it is desired to use the connector 104 on both opposed faces of the printed circuit board 102. In the example shown, two of the vias 502 are for pins 202 (not shown in FIG. 5A, but see FIG. 2) carrying a differential pair transmitter signal, and these pins 202 are to be inserted through the top face of the printed circuit board 102. The original design for single-sided mounting of the connector 104 to the printed circuit board called for two ground vias 508 through the printed circuit board, to accompany and provide ground return paths for signal activity on the differential pair transmitter signal carried through the vias 502. Two more of the vias 504 are for pins 202 carrying a differential pair receiver signal, and these pins 202 are to be inserted through the bottom face of the printed circuit board 102. The original design for single-sided mounting of the connector 104 to the printed circuit board called for two ground vias 506, to accompany and provide ground return paths for signal activity on the differential pair receiver signal carried through the vias 504. Combining these requirements leads to the short-circuit problem between ground vias 506 and signal vias 502, and between ground vias 508 and signal vias 504. Ground pin vias 510, for ground pins of the connectors 104, do not interfere, and are acceptable as-is in the design.

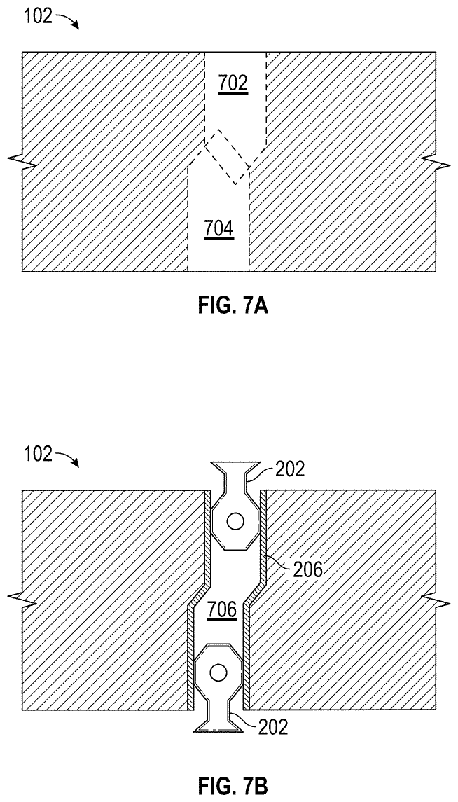

FIG. 5B is a top projected view that depicts a solution to the problem of FIG. 5A, with a solitary or singular ground via 512 adjacent to two signal vias 502, 504. This arrangement is repeated with another solitary or singular ground via 512 adjacent to the two other signal vias 502, 504. It is readily discerned that the placement of the solitary or singular ground via 512 solves the spacing issues, so that there is no short-circuit as in FIG. 5A. What is not so visible is how the solitary or singular ground via 512 works to provide a ground return path for each of the two signals, which is shown in FIG. 6. In one embodiment, the signal vias 502 for the differential pair transmit (TX) pins 206 (see FIG. 6) have the transmit pins 206 inserted from the top face of the printed circuit board 102, and the signal vias 504 for the differential pair receive (RX) pins 206 (see FIG. 6) inserted from the bottom face of the printed circuit board 102.

FIG. 6 depicts the via arrangement of FIG. 5B in a lateral projected cross-section view, showing ground return paths through the solitary or singular ground via 512 for two signals with pins 202 on opposed faces of the printed circuit board 102. Details of the back drilling to produce the signal vias 502, 504 (see, e.g., FIG. 4) are omitted so that the projected view of FIG. 6 can be shown without interfering lines in the drawing. That is, per FIG. 5B, the signal via 502 for one of the transmit signal pins 206 has the pin 206 inserted into the via 502 from the top face of the printed circuit board 102, and the signal via 504 for one of the received signal pins 206 has the pin 206 inserted into the via 504 from the bottom face of the printed circuit board 102. The solitary ground via 512 is immediately adjacent to these signal vias 502, 504. Again per FIG. 5B, the solitary ground via 512 and the two signal vias 502, 504 are not actually coplanar, although they appear so due to the projected cross-section view of FIG. 6. In a further embodiment, the solitary ground via 512 and the two signal vias 502, 504 could be coplanar, with the signal vias 502, 504 as blind vias that connect an internal layer(s) to an outer layer but do not go all the way through the printed circuit board 102. Each such blind via could be produced with two controlled depth drillings and plating, without the back drilling, or by drilling in the layers of the printed circuit board 102 prior to lamination, in various embodiments.

The singular or solitary ground via 512 is plated throughout, with plating 206 extending to both faces of the printed circuit board 102. In some embodiments, the singular or solitary ground via 512 has no mechanical connection to any connector pin, and can be a minimum width via.

Signal current 610 from signal activity on the transmit pin 202 travels back and forth in the plating 206 on the transmit pin signal via 502. This signal current 610 induces a ground return current 606 in an upper portion of the solitary or singular ground via 512 and a portion of the upper ground plane 602, to which the singular or solitary ground via 512 is connected. Similarly, signal current 612 from signal activity on the receive pin 202 travels back and forth in the plating 206 on the receive pin signal via 504. This signal current 612 induces a ground return current 608 in a lower portion of the solitary or singular ground via 512 and a portion of the lower ground plane 602, to which the singular or solitary ground via 512 is also connected. The solitary or singular ground via 512 thus serves to produce ground return currents 606, 608 for both of the adjacent signal vias 502, 504. There is thus no requirement, in this arrangement, that each signal via should have its own ground via, which would result in there being two ground vias for the two signal vias 502, 504.

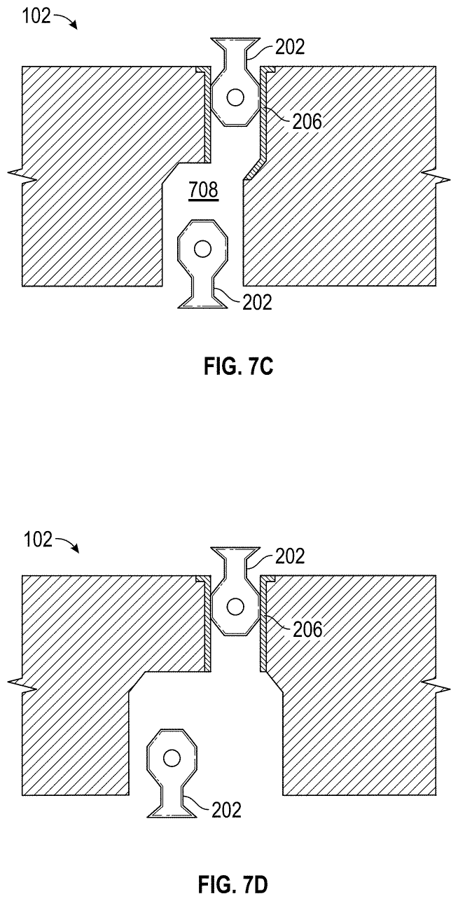

FIG. 7A depicts offset back drilling in the printed circuit board 102. In a process for back drilling, the first drilling 702 (depicted in dashed outline) is to a first controlled depth from one face of the printed circuit board 102. The second drilling 704, offset from the first drilling 702, is to a second controlled depth from a second opposed face of the printed circuit board 102. The two drillings 702, 704 should be arranged so that there is overlap at the controlled depth of each drilling 702, 704, and so that the passages meet in the center or at least in the interior of the printed circuit board 102. The two controlled depths are not required to be identical, although when they are, this produces a symmetric depth offset back drilling. This process is followed by plating the resultant via. No pilot hole, through the entire thickness of the printed circuit board 102 (e.g., an initial, straight through hole), is required prior to the two controlled depth back drillings. Generally, each drilling 702, 704 should use a greater than minimum diameter for a given printed circuit board manufacturing process, as it would be difficult to make minimum diameter controlled depth holes meet.

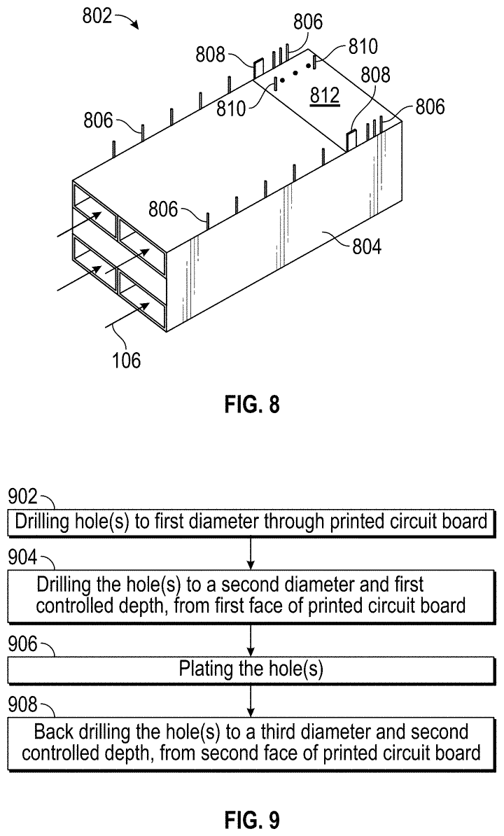

FIG. 7B is a cross-section view of the printed circuit board, showing a staggered via 706 produced by the offset back drilling of FIG. 7A. Offsetting one drilling 704 with respect to the other drilling 702 (as shown in FIG. 7A) results in the first section of the via 706 being staggered relative to the second section of the via 706. The stagger or offset in the walls of the via 706, from one face of the printed circuit board 102 relative to the other, opposed face of the printed circuit board 102, make the staggered via 706 suitable for offset pins 202 inserted from opposing faces of the printed circuit board 102. These could be ground pins, power pins, or signal pins, e.g., from opposed connectors 104. In one embodiment, the pins 202 are press-fit cage pins from the connectors (see FIG. 8). Plating 206 electrically connects the two pins 202, and can also connect to one or more ground planes, power planes, or signal traces of the printed circuit board 102, depending upon the pin connection requirements for a given design.

FIG. 7C is a cross-section view of the printed circuit board 102, showing a variation of the staggered via 706 of FIG. 7B. In this embodiment, one portion of the via 708 is drilled and has plating 206 to fit a pin 202 inserted from one face of the printed circuit board 102. The other portion of the via 708 has an offset back drilling to a larger diameter, so that the walls of that portion of the via 708 do not contact the pin 202 inserted from the opposed face of the printed circuit board 102. In a further variation, the portion of the via 708 that does not contact the pin 202 is produced by a larger diameter back drilling but without an offset. The larger diameter back drilling, for any of these versions, can be performed after the plating 206 is deposited, so that there is no electrical conductivity available to that pin 202 in the via 708. Or, in a still further variation, plating 206 could be applied after the larger diameter back drilling. As an example of how this could be used with various connectors 104, the larger diameter back drilling could be made at alternating locations on top and bottom of the printed circuit board 102, so that alternating ground cage pins (see FIG. 8) of each of two opposed connectors 104 do not connect to ground of the printed circuit board 102, while the remaining other, alternating ground cage pins of each of the two opposed connectors 104 do connect to ground of the printed circuit board 102.

FIG. 7D is a cross-section view of the printed circuit board, showing a further variation of the staggered via of FIG. 7B. In this version, the second back drilling 708 is of an even larger diameter than in FIG. 7C. Various offsets could be tried, producing various amounts of stagger for the walls in the staggered via 710.

FIG. 8 is a perspective view of a QSFP (quad small form factor pluggable) connector 802, suitable for use in embodiments of the present disclosure. Four cables 106 (one for each channel) are inserted through a 2×2 arrangement of openings at one end of the connector 802. A variety of pins project from one face of the connector 802. Cage pins 806 project along sides of the cage 804 (i.e., box, case, or housing) of the connector 802. These are grounded, press-fit pins in some embodiments. Plastic alignment pins 808 project from two locations along the sides of the cage 804 of the connector 802. In some embodiments, the plastic alignment pins 808 are deleted, removed, or otherwise not present on the QSFP connector 802, so that a thinner thickness of printed circuit board 102 can be used than would otherwise be possible with the plastic alignment pins 802 intact. This solves a problem arising from plastic alignment pins 802 from opposed connectors 802 otherwise interfering in such a thin printed circuit board 102. Signal and power pins 810 project from a signal and power pin region 812 of the connector 802. Generally, the cage pins 806 are of a larger width than the signal and power pins 810, and have correspondingly larger diameter holes for the vias in the printed circuit board 102 as compared to vias for signals. Sixteen QSFP connectors 802 can be mounted to the printed circuit board 102 as shown in FIG. 1A, eight to one face, and eight more to an opposed face of the printed circuit board 102, using various combinations of embodiments of vias as shown and described herein, and variations thereof.

FIG. 9 is a flow diagram of a method for making a printed circuit board, which can produce the embodiments shown in FIGS. 4 and 6 and variations thereof. Drilling can be done with drill bits or lasers, etc., and should be dimensioned as to width, depth, and arrangement so that, with plating, the vias so produced fit the desired connectors and pins. In an action 902, holes are drilled, to a first diameter, through the printed circuit board. In an action 904, the holes are back drilled to a second diameter and first controlled depth, from a first face of the printed circuit board. In an action 906, the holes are plated. In an action 908, the holes are back drilled to a third diameter and second controlled depth, from a second face of the printed circuit board. The controlled depths do not need to be identical, but could be for symmetry. Various possibilities and reasons for selecting specific widths for the various drillings and controlled depths for the back drillings are discussed with reference to FIG. 4.

Drilling the holes to the first diameter all the way through the printed circuit board, in the action 402, has advantages for alignment for each of the first and second back drilling operations. However, variations of the method could be performed in which the action 402 drills only part way through the printed circuit board, and one of the back drillings is aligned using markings, projections, other holes, or other features on the printed circuit board rather than aligning to a hole drilled all the way through the printed circuit board.

The method can also be performed by repeating with the first and second faces of the printed circuit board swapped, so that the back drilled dual-diameter vias are produced in opposing orientations, as depicted in FIG. 4. The method can be performed by omitting the second back drilling operation, the action 408, so that dual-diameter vias as depicted in FIG. 3 are produced.

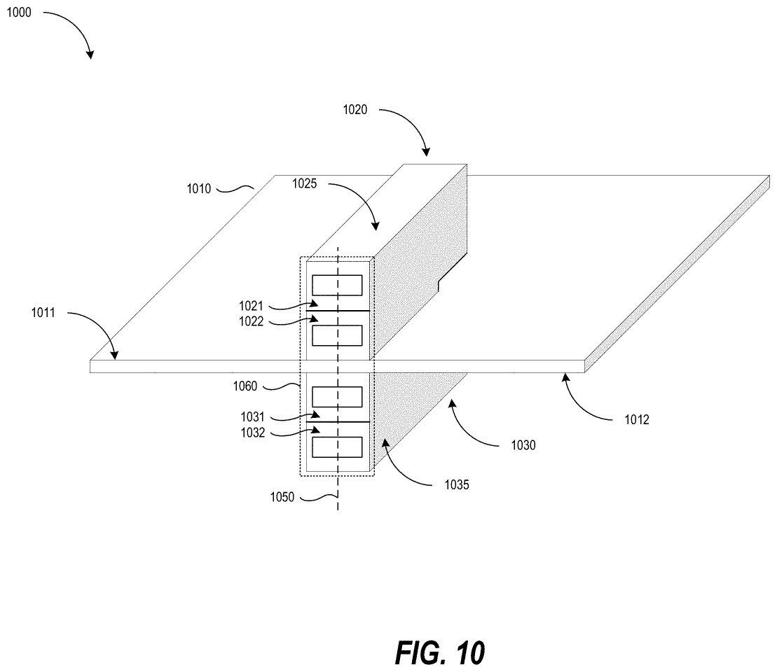

FIG. 10 illustrates a perspective view (e.g., an isometric view) of a network device 1000 in accordance with one or more embodiments of the present disclosure. The network device 1000 includes a printed circuit board (PCB) 1010. The PCB 1010 may include a first surface 1011 (e.g., a top or upper surface) and a second surface 1012(e.g., a bottom or lower surface). Various devices, components, circuits, etc., may be included in the PCB 1010 (e.g., may be mounted, positioned, or located on the first surface 1011 and/or the second surface 1012). For example, the PCB 1010 may include one or more connectors (no illustrated in FIG. 1) that may couple the network device 1000 to other devices, components, etc. The one or more connectors may couple the PCB 1010 (and other devices, components, circuits, etc.) to a mid-plane or a backplane of a network element (e.g., a mid-plane of a network switch). In another example, the PCB 1010 may include processing devices (e.g., an applicant specific integrated circuit (ASIC), a processor, etc.) that may process and/or analyze data (e.g., packets) that may be transmitted/received by the network device 1000.

In one embodiment, the network device 1000 includes a first small format pluggable (SFP) module 1020 coupled to the PCB 1010 on a first surface 1011 of the PCB 1010. The first surface 1011 may be an upper surface or a top surface of the PCB 1010. In other embodiments, the first surface may be a lower surface or bottom surface if the orientation of the network device 1000 is reversed (e.g., if the network device 1000 is flipped upside down). The first SFP module 1020 includes two SFP modules that are vertically stacked. For example, the first SFP module 1020 may include a first SFP module 1021 that is positioned and/or located above a second SFP module 1022. In another example, the first SFP module 1021 and the second SFP module 1021 may be aligned along a same vertical axis. The first SFP module 1021 and the second SFP module 1022 may be located within a housing 1025 for the first SFP module 1020 (e.g., with a single housing, within the same housing, etc.).

In one embodiment, the network device 1000 includes a second octal small format pluggable (SFP) module 1030 coupled to the PCB 1010 on a second surface 1012 of the PCB 1010. The second surface 1012 may be a lower surface or a bottom surface of the PCB 1010. In other embodiments, the second surface may be a top surface or upper surface if the orientation of the network device 1000 is reversed (e.g., if the network device 1000 is flipped upside down). The second SFP module 1030 includes two SFP modules that are vertically stacked. For example, the second SFP module 1030 may include a first SFP module 1031 that is positioned and/or located above a second SFP module 1032. In another example, the first SFP module 1031 and the second SFP module 1031 may be aligned along a same vertical axis. The first SFP module 1031 and the second SFP module 1032 may be located within a housing 1035 for the second SFP module 1030.

In some embodiments, the SFP module 1020 and the SFP module 1030 may be referred to as stacked SFP modules. A stacked SFP module may include multiple SFP modules that are positioned above each other such that portions of the multiple SFP modules overlap with each other in a horizontal dimension (e.g., along the X-axis). In other embodiments, the SFP module 1020 and the SFP module 1030 may be quad small form-factor pluggable (QSFP) modules. Although the present disclosure may refer to SFP or QSFP modules, other types of network modules may be used in other embodiments.

In one embodiment, the bottom of the first SFP module 1020 may be flush and/or parallel with the top surface 1011 of the PCB 1010. For example, at least a portion of the bottom of the housing 1025 for the first SFP module 1020 may be positioned flush with and/or parallel to the top surface 1011 of the PCB 1010, as discussed in more detail below. In another embodiment, the bottom of the second SFP module 1030 may be flush and/or parallel with the bottom surface 1012 of the PCB 1010. For example, at least a portion of the bottom of the housing 1035 for the second SFP module 1030 may be positioned flush with and/or parallel to the bottom surface 1012 of the PCB 1010. A stacked SFP module may be flush with the a surface of the PCB 1010 if a portion of the stacked SFP module (e.g., a portion of the housing) is touching the PCB 1010, in contact with the PCB 1010, even with a surface of the PCB 1010, level with a surface of the PCB 1010, parallel with a surface of the PCB 1010, etc.

In one embodiment, a first center of the first SFP module 1020 may be aligned with a second center of the second SFP module 1030 along a same vertical axis and/or vertical plane. For example, as illustrated by line 1050, the center of the first SFP module 1020 may be aligned with the center of the second SFP module 1030. The vertical axis (illustrated by line 1050) and/or the vertical plane may divide each of the first SFP module 1020 and the second SFP module 1030 in half.

In one embodiment, the first SFP module 1020 and the second SFP module 1030 may form a column 1060. The column 1060 may include multiple SFP modules. For example, the column 1060 may include two SFP modules from the first SFP module 1020 and may include two SFP modules from the second SFP module 1030 for a total of four SFP modules. The orientation of the first SFP module 1020 and the second SFP module 1030 in the column 1060 may be referred as a belly-to-belly orientation because the bottoms of the housings 1025 and 1035 are positioned adjacent to each other. For example, the orientation of the first SFP module 1020 and the second SFP module 1030 in the column 1060 may be referred as a belly-to-belly orientation because the first SFP module 1020 is opposed to the second SFP module 1030.

In one embodiment, the first SFP module 1020 and the second SFP module 1030 may be coupled to the PCB 1010 using vias through the PCB 1010. Vias may be holes, openings, apertures, etc., that that go partially and/or completely through the PCB 1010, as illustrated and discussed above. The vias may include a conductive material, surface, and/or coating (e.g., a metallic surface/coating) that may be used to electrically and/or thermally couple connector pins of the first SFP module 1020 and the second SFP module 1030 to other wires, pins, traces, cables, devices, components, circuits, etc., that are within or coupled to the PCB 1010. A first set of connector pins for the first SFP module 1020 may align with a first set of vias of the PCB and a second set of connector pins for the second SFP module 1030 may align with the second set of vias of the PCB 1010, as discussed in more detail below.

In some embodiments, the first set of vias (coupled to the first SFP module 1020) and the second set of vias (coupled to the second SFP module 1030) may be offset from each other. For example, the first set of vias may be located to the left, right, top, or bottom of the second set of vias, as discussed in more detail below.

As illustrated in FIG. 1, the front of the first SFP module 1020 and front of the second SFP module 1030 may be flush with the edge of the PCB 1010. In other embodiments, the first SFP module 1020 and the second SFP module 1030 may be positioned differently. For example, the fronts of the first SFP module 1020 and the second SFP module 1030 may protrude outward from the edge of the PCB 1010. In another example the fronts of the first SFP module 1020 and the second SFP module 1030 may be within the outer edges of the PCB 1010.

Although two SFP modules are illustrated and discussed herein, any number of SFP modules may be coupled to the PCB 1010 in other embodiments. For example, there may be seven SFP modules coupled to the first surface 1011 of the PCB 1010 and seven SFP modules coupled to the first surface 1012 of the PCB 1010. In addition, although SFP modules are illustrated and discussed herein, a stacked SFP module may include more than two SFP modules in other embodiments. For example, a stacked SFP module may include three, eight, or any appropriate number of SFP modules in other embodiments.

As discussed above, network element (e.g., network element 900 illustrated in FIG. 9) may include a chassis with one or more slots. Network devices, such as line cards, may be inserted into the slots. The size of the chassis may limit the number of slots and thus, the number of network devices (e.g., line cards) that may be used in a network element. As network requirements increase, it may be useful to increase the capabilities of a network element without increasing the size of the chassis and/or without increasing the number of slots in a chassis. The embodiments, examples, and/or implementations described herein allow for stacked SFP modules to be coupled to a PCB in a belly-to-belly orientation. This may allow for the capabilities and/or capacity of a network device to be increased without increasing the number of network devices or slots in a network element. For example, by arranging the stacked SFP modules in a belly-to-belly orientation/configuration, the number of SFP modules on a network device may be doubled, which may increase the capacity/capabilities of the network device. In addition, this may also decrease the cost to manufacture the network device (e.g., a line card) because a single PCB may be used for the stacked SFP modules, rather than using two PCBs. Reducing the number of PCBs used may also decrease the cost to manufacture a network element (e.g., a network switch) because fewer connectors may be used to couple the PCBs to the network element. This may also reduce the complexity of the network element (e.g., reduce the number of wires, pins, traces, connectors, etc., that may be used in the network element). Furthermore, the embodiments, examples, and/or implementations described herein allow identical SFP modules to be stacked belly-to-belly by using a pin layout that allows power pins and/or ground pins to be inserted into common vias. This may also reduce the cost and/or complexity of manufacturing a network device and/or network element.

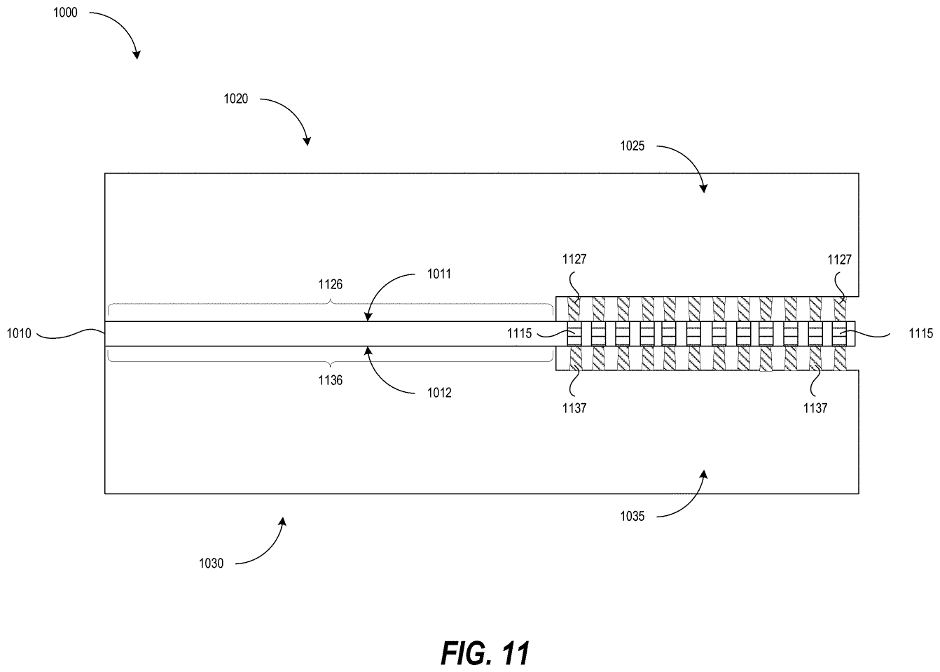

FIG. 11 is a side view of a network device 1000 in accordance with one or more embodiments of the present disclosure. The network device 1000 includes a PCB 1010 that includes a first surface 1011 and a second surface 1012. Various devices, components, circuits, etc., may be included in and/or coupled to the PCB 1010. The network device 1000 includes a first SFP module 1020 coupled to the PCB 1010 on the first surface 1011 and a second SFP module 1030 coupled to the PCB 1010 on a second surface 1012. The first SFP module 1020 and the second SFP module 1030 each include two SFP modules (or more) that are vertically stacked, as discussed above. A portion 1126 of the bottom of the first SFP module 1020 (e.g., at least a portion of the housing 1035) may be flush and/or parallel with the top surface 1011 of the PCB 1010. A portion 1136 of the bottom of the second SFP module 1030 (e.g., at least a portion of the housing 1035) may be positioned flush with and/or parallel to the bottom surface 1012 of the PCB 1010.

As discussed above, the first SFP module 1020 and the second SFP module 1030 may be coupled to the PCB 1010 using vias 1115 (e.g., a set of vias, a group of vias, a plurality of vias, etc.). The vias 1115 may include a conductive material, surface, coating, etc. that may be used to electrically and/or thermally couple connector pins 1127 of the first SFP module 1020 and connector pins 1137 of the second SFP module 1030 to other wires, pins, traces, cables, devices, components, circuits, etc., that are within or coupled to the PCB 1010. The connector pins 1127 for the first SFP module 1020 may align with a first set of the vias 1115 of the PCB and the connector pins 1137 for the second SFP module 1030 may align with a second set of the vias 1115 of the PCB 1010, as discussed above. When the first SFP module 1020 is coupled to the PCB 1010, at least portions of the connector pins 1127 may be inserted into the first set of the vias 1115. When the second SFP module 1030 is coupled to the PCB 1010, at least portions of the connector pins 1137 may be inserted into the second set of the vias 1115.

The vias 1115 may be divided into different subsets or subgroups of vias, as discussed in more detail below. For example, the vias 1115 may be divided into two subsets of vias. The first subset of vias may interface with the connector pins 1127 of the first SFP module 1020. The second subset of vias may interface with the connector pins 1137 of the second SFP module 1030. At least some of the vias 1115 may be part of (e.g., may be included in) the first subset of vias and the second subset of vias, as discussed in more detail below. The vias 1115 that are part of the first subset of vias and the second subset of vias may be referred to as common vias or overlapping vias. In one embodiment, the common vias may be coupled to a power source (e.g., a power plane, a power supply, etc.) through connections of the PCB 1010 (e.g., wires, pins, connections, traces, etc.). In another embodiment, the common vias may be coupled to a ground through connections of the PCB 1010 (e.g., internal wires, pins, connections, traces, etc.). The common vias may allow the first SFP module 1020 and the second SFP module 1030 to be press-fit onto the PCB 1010, as discussed in more detail below. This may also allow first SFP module 1020 and the second SFP module 1030 to be identical, as discussed in more detail below. For example, the same part or SFP module may be used on both sides of the PCB 1010.

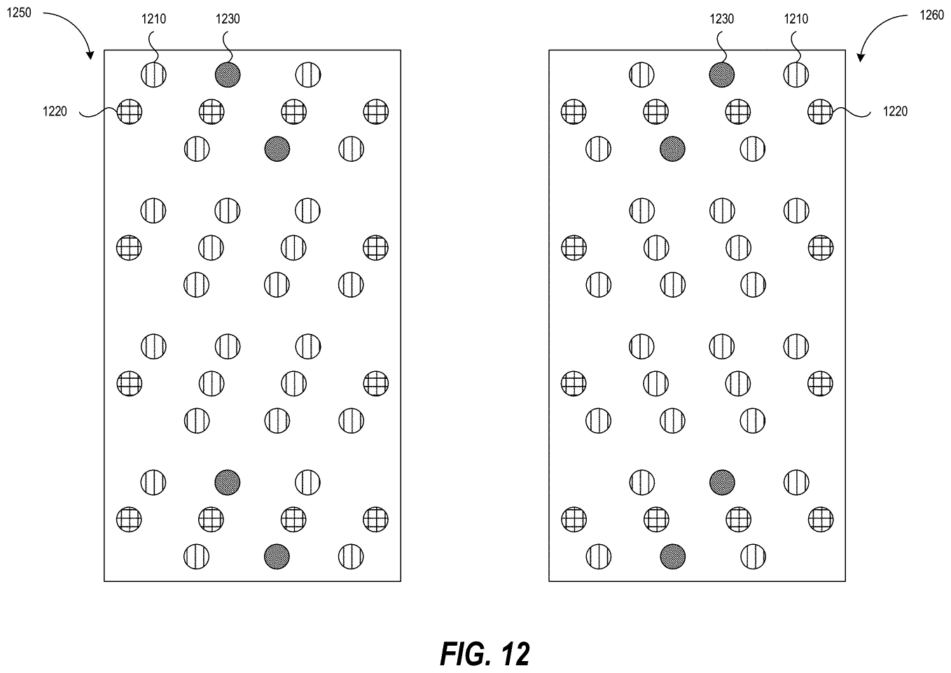

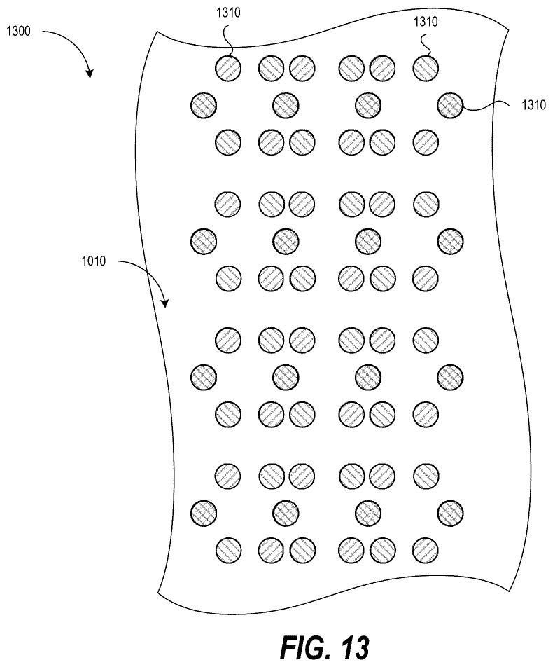

FIG. 12 is a diagram illustrating example pin layouts 1250 and 1260 for SFP modules 1010 and 1020 in accordance with one or more embodiments of the present disclosure. A pin layout may refer to a set of connector pins that are positioned in various areas/locations (e.g., a pin layout may be an arrangement of connector pins). A pin layout may also be referred to as a pin configuration. The connections pins are illustrated as circles in FIG. 12. In one embodiment, the connector pins for the pin layout 1250 may include three types of connections pins. A first type of connector pin may be a data pin 1210. The data pins 1210 are represented by vertically hashed circles. The data pins 1210 may communicate data (e.g., signals, bits, packets, frames, etc.) between an SFP module and connections of a PCB (which may be coupled to other components, such as processors, other SFP modules, memories, etc.). A second type of connector pin may be a power pin 1220. The power pins 1220 are represented by checked circles. The power pins 1220 may be used to receive power from a power source (e.g., a power supply, a power plane, etc.) and provide the power to the SFP module. A third type of connector pin may be a ground pin 1230. The ground pins 1230 are represented by solid shaded circles. The ground pins 1230 may be used to couple the SFP module or a portion of the SFP module to ground (e.g., to a ground plane). The pin layout 1260 may also include data pins 1210, power pins 1220, and ground pins 1230.

FIG. 13 is an overhead view of a portion 1300 of printed circuit board (PCB) 1010 in accordance with one or more embodiments of the present disclosure. As discussed above, the PCB 1010 includes vias 1310 which are represented as hashed circles in FIG. 13. The vias 1310 may include multiple subsets of multiple subgroups. For example, the vias 1310 may be divided in to a first subset and a second subset. The first subset of the vias 1310 may be represented by circles that include an upward diagonal hashing. For example, the top left via 1310 may be part of the first subset of the vias 1310. The second subset of the vias 1310 may be represented by circles that include a downward diagonal hashing. For example, the top right via 1310 may be part of the second subset of the vias 1310. As discussed above, one or more of the vias 1310 may be in the first subset and the second subset of the vias 1310. The vias 1310 that may be part of the first subset and the second subset of the vias 1310 may be represented by circles that include diagonal cross hashing. The vias 1310 that may be part of the first subset and the second subset of the vias 1310 may be referred to as common vias or overlapping vias. Details of how the vias 1310 may be created (e.g., drilled), oriented, positioned, located, etc., are discussed in more detail above in conjunction with FIGS. 1 through 9.

The first subset of the vias 1310 may interface with connector pins of a first SFP module (e.g., SFP module 1020) and the second subset of the vias 1310 may interface with connector pins of a second SFP module. For example, the first SFP module may be coupled to the PCB 1010 using the first subset of the vias 1310 and the second SFP module may be coupled to the PCB 1010 using the second subset of the vias 1310. The vias 1310 may include a conductive material, surface, coating, etc. that may be used to electrically and/or thermally couple connector pins of the first SFP module and the second SFP module to other wires, pins, traces, cables, devices, components, circuits, etc., that are within or coupled to the PCB 1010. The connector pins for the first SFP module may align with the first subset of the vias 1310 of the PCB and the connector pins for the second SFP module may align with the second subset of the vias 1310 of the PCB 1010. The common vias (represented by circles that include diagonal cross hashing) may align with connector pins from both the first SFP module and the second SFP module.

When the first SFP module is coupled to the PCB 1010, at least portions of the connector pins may be inserted into the first subset of the vias 1310. When the second SFP module is coupled to the PCB 1010, at least portions of the connector pins may be inserted into the second subset of the vias 1310. As illustrated in FIG. 13, the some of the first subset of the vias 1310 may be offset (e.g., located to the left, right, top or bottom) from some of the second subset of the vias 1310. In addition, some of the vias 1310 may be included in the first subset and the second subset of the vias 1310 (e.g., may overlap). The offsetting of some of the first subset and the second subset of the vias 1310 and the overlapping of others of the first subset and the second subset of the vias 1310 allows the first SFP module and the second SFP module to be coupled to the PCB 1010 in a belly-to-belly configuration by press-fitting. This also allows the housings of the first SFP module and the second SFP module to be the same length while keeping the connector pins of the first SFP module and the second SFP module properly aligned with the vias 1310.

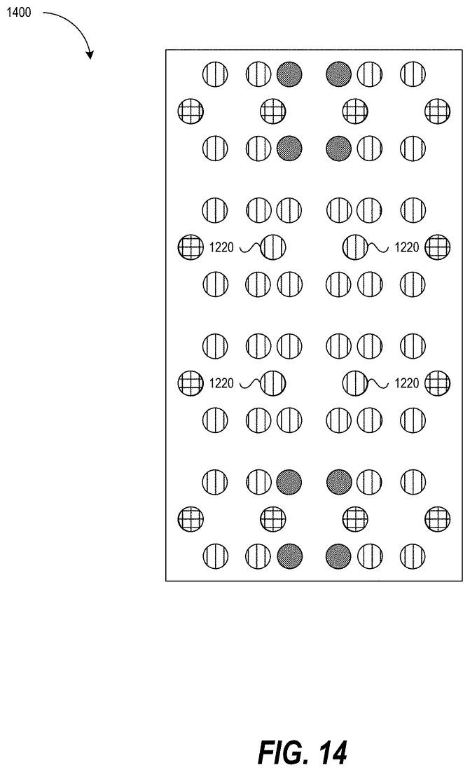

FIG. 14 is a diagram illustrating a combined pin layout 1400 in accordance with one or more embodiments of the present disclosure. The combined pin layout 1400 may be a combination of the pin layouts 1250 and 1260 (for SFP modules 1010 and 1020) illustrated in FIG. 13. As illustrated in FIG. 14, when the pin layouts 1250 and 1260 are combined to form the combined pin layout 1400, four of the data pins 1210 (indicated in FIG. 14) may overlap. For example, the four data pins 1210 may be inserted into the same vias of a PCB when the SFP modules 1010 and 1020 are coupled to the PCB. Because the four data pins 1210 may be inserted into the same vias of a PCB, this may cause various problems and/or issues during the operation of a network device (e.g., a lined card). For example, the data pins 1210 may short circuit each other because they are inserted into the same vias of the PCB. In another example, data may not be communicated properly using the connections pins that are inserted in to the same vias of the PCB because the data/signals from the data pins of the first SFP module 1010 may interfere with the data/signals from the data pins of the second SFP module 1020.

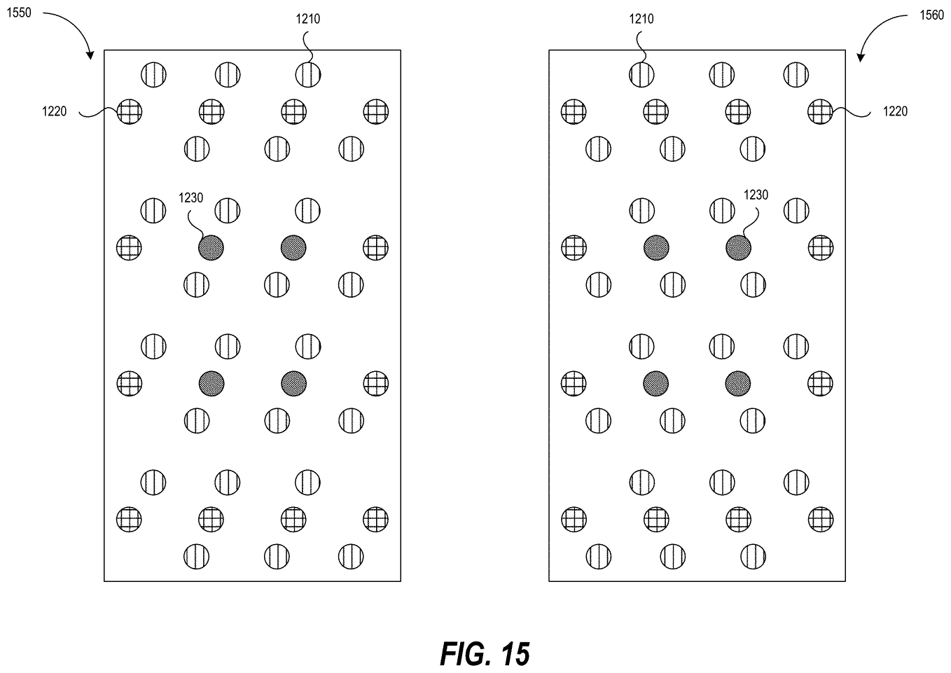

FIG. 15 is a diagram illustrating example pin layouts 1550 and 1560 for SFP modules 1010 and 1020 in accordance with one or more embodiments of the present disclosure. As discussed above, a pin layout may refer to a set of connector pins that are positioned in various areas/locations (e.g., a pin layout may be an arrangement of connector pins). A pin layout may also be referred to as a pin configuration. The connections pins are illustrated as circles in FIG. 15. In one embodiment, the connector pins for the pin layout 1550 may include three types of connections pins. A first type of connector pin may be a data pin 1210. The data pins 1210 are represented by vertically hashed circles. The data pins 1210 may communicate data (e.g., signals, bits, packets, frames, etc.) between an SFP module and connections of a PCB (which may be coupled to other components, such as processors, other SFP modules, memories, etc.). A second type of connector pin may be a power pin 1220. The power pins 1220 are represented by checked circles. The power pins 1220 may be used to receive power from a power source (e.g., a power supply, a power plane, etc.) and provide the power to the SFP module. A third type of connector pin may be a ground pin 1230. The ground pins 1230 are represented by solid shaded circles. The ground pins 1230 may be used to couple the SFP module or a portion of the SFP module to ground (e.g., to a ground plane). The pin layout 1560 may also include data pins 1210, power pins 1220, and ground pins 1230.

As discussed above, a first SFP module couple to a PCB may be identical to a second SFP module that is coupled to the PCB. The second SFP module may be oriented upside down with respect to the first SFP module. For example, referring to FIG. 10, the SFP module 1030 may be oriented upside down with respect to SFP module 1020 when the SFP modules 1020 and 1030 are arranged in a belly-to-belly configuration. Thus, the pin layout 1550 (for a first SFP module) may be a mirror image or a reverse image of the pin layout 1560 (for a second SFP module) when the first SFP module and the second SFP module are arranged in a belly-to-belly configuration. The pin layout 1550 may be identical to the pin layout 1560 when the first SFP module and the second SFP module are both oriented in the same direction and/or facing the same direction.

Referring to FIG. 12, the pin layouts 1250 and 1260 may differ from the pin layouts 1550 and 1560 in that the locations of the ground pins 1230 have been swapped with the locations of some of the data pins 1210. The ground pins 1230 of the SFP modules 1010 and 1020 may be inserted into common vias (e.g., overlapping vias) when the locations of the ground pins 1230 are swapped with the locations of some of the data pins 1210. Thus, some of the ground pins 1230 of the first SFP module may be coupled to the same ground as some of the ground pins of the second SFP module. Because a ground may be shared between multiple connections, swapping the locations of the ground pins 1230 with the locations of some of the data pins 1210 may help the pin layouts avoid some of the problems/issues discussed above. For example, the data pins 1210 of different SFP modules may no longer short circuit each other because they are inserted into the different vias of the PCB. In another example, data may be communicated properly through the data pins 1210 because the data/signals from the data pins of the first SFP module 1010 may not interfere with the data/signals from the data pins of the second SFP module 1020.

In some embodiments, a pin layout may be different from the pin layouts 1250 and 1260 by swapping the locations of some of the power pins 1220 with some of the data pins 1210. Some of the power pins 1220 of the SFP modules 1010 and 1020 may be inserted into common vias (e.g., overlapping vias) when the locations of those power pins 1220 are swapped with the locations of some of the data pins 1210. Thus, some of the power pins 1220 of the first SFP module may be coupled to the same power source as some of the power pins of the second SFP module. Because a power source may be shared between multiple connections, swapping the locations of some of the power pins 1220 with the locations of some of the data pins 1210 may help the pin layouts avoid some of the problems/issues discussed above. For example, the data pins 1210 of different SFP modules may no longer short circuit each other because they are inserted into the different vias of the PCB. In another example, data may be communicated properly through the data pins 1210 because the data/signals from the data pins of the first SFP module 1010 may not interfere with the data/signals from the data pins of the second SFP module 1020.

In other embodiments, a pin layout may different from the pin layouts 1250 and 1260 by some of the power pins 1220 and some of the ground pins 1230 with some of the data pins 1210. This may allow those power pins 1220 to be inserted into common vias that may be coupled to a power source and may also allow those ground pins to be inserted into common vias that may be coupled to a ground.

Although example pin layouts are illustrated and discussed herein, other embodiments may use different pin layouts. For example, the number and/or arrangement of pins in the pin layouts may vary in different embodiments. In another example, different embodiments of pin layouts may include other types of pins besides the data pins, power pins, and/or ground pins discussed herein.

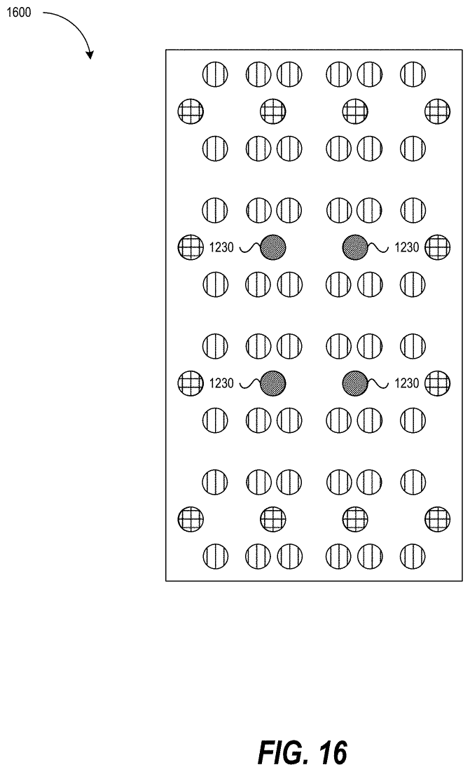

FIG. 16 is a diagram illustrating a combined pin layout 1600 in accordance with one or more embodiments of the present disclosure. The combined pin layout 1600 may be a combination of the pin layouts 1550 and 1560 (for SFP modules 1010 and 1020) illustrated in FIG. 15. As illustrated in FIG. 16, when the pin layouts 1550 and 1560 are combined to form the combined pin layout 1600, the ground pins 1230 (indicated in FIG. 16) may overlap. For example, the four data pins 1510 may be inserted into the same vias of a PCB when the SFP modules 1010 and 1020 are coupled to the PCB.

As discussed above, the locations of the ground pins 1230 have been swapped with the locations of some of the data pins 1210 when comparing the combined pin layout 1600 with the pin layouts 1250 and 1260 illustrated in FIG. 12. This may allow the ground pins 1230 of the SFP modules 1010 and 1020 to be inserted into common vias (e.g., overlapping vias) when the locations of the ground pins 1230 are swapped with the locations of some of the data pins 1210. Because a ground may be shared between multiple connections, swapping the locations of the ground pins 1230 with the locations of some of the data pins 1210 may help the pin layouts avoid some of the problems/issues discussed above. For example, the data pins 1210 of different SFP modules may no longer short circuit each other because they are inserted into the different vias of the PCB. In another example, data may be communicated properly through the data pins 1210 because the data/signals from the data pins of the first SFP module 1010 may not interfere with the data/signals from the data pins of the second SFP module 1020. As illustrated in FIGS. 15 through 16, at least portions of ground pins 1230 of the SFP modules 1010 and 1020 may overlap with each other in a horizontal dimension (e.g., along the X-axis).

As discussed, in some embodiments (not illustrated in the figures), the locations of some of the power pins 1220 may be swapped with some of the data pins 1210. This may allow some of the power pins 1220 of the SFP modules 1010 and 1020 to be inserted into common vias (e.g., overlapping vias). Because a power source may be shared between multiple connections, swapping the locations of some of the power pins 1220 with the locations of some of the data pins 1210 may help the pin layouts avoid some of the problems/issues discussed above. In other embodiments, some of the power pins 1220 and some of the ground pins 1230 may be swapped with some of the data pins 1210. This may allow those power pins 1220 to be inserted into common vias that may be coupled to a power source and may also allow those ground pins to be inserted into common vias that may be coupled to a ground.

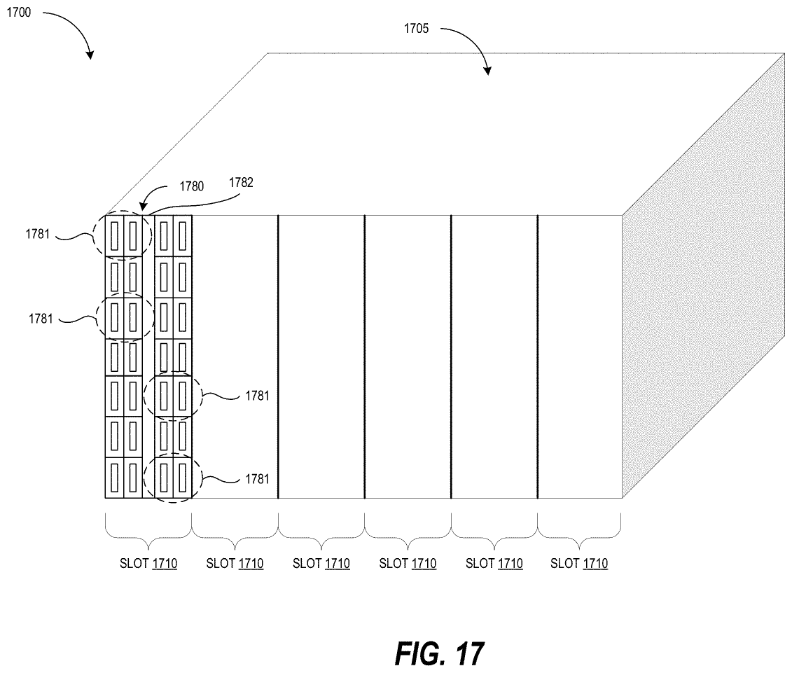

FIG. 17 is a perspective view of a network element 1700 in accordance with one or more embodiments of the present disclosure. The network element 1700 includes a chassis 1705. The chassis 1705 may enclose network devices (e.g., line cards, control cards, etc.) and/or other components of the network device 1780 (e.g., circuits, processing devices, memory, circuit boards, power supplies, etc.). The chassis 105 may also enclose (fully or partially) the network device 1780 (e.g., a line card). The network device 100 includes multiple slots 1710. A network device (e.g., a line card such as network device 1780 illustrated above, etc.) may be inserted into each of the slots 1710. As illustrated in FIG. 17, the network device 1780, a PCB 1782, and a plurality of stacked SFP modules 1781 are coupled to the PCB 1782 (similar to network device 100 illustrated above). Each stacked SFP module includes two SFP modules, as discussed above. The network device 1780 includes seven rows of stacked SFP modules, with each row of stacked SFP modules including a total of four SFP modules. The orientation of the first stacked SFP module and the second stacked SFP module in each row may be referred as a belly-to-belly orientation because the bottoms of the housings and are positioned adjacent to each other.

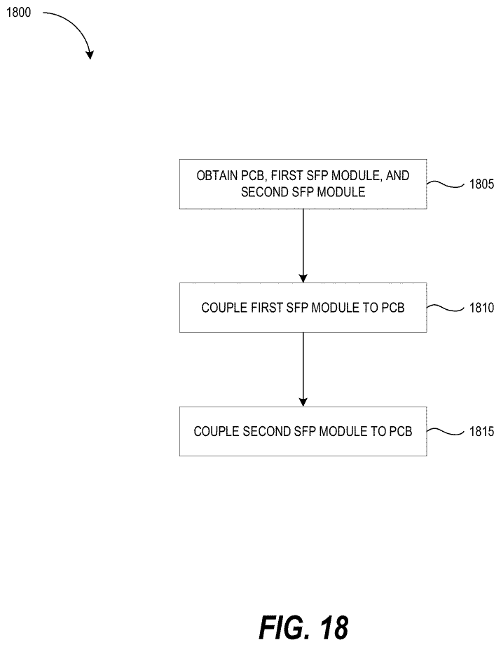

FIG. 18 is a flow diagram of a method 1800 of assembling a network device in accordance with one or more embodiments of the present disclosure. It should be appreciated that the blocks of the method 1800 in FIG. 18 can be performed in differing orders, groupings, or subsets than shown in FIG. 18, for various purposes or user preferences. At block 1805, a PCB, a first SFP module, and a second SFP module are obtained. The PCB includes a set of vias (as illustrated in FIG. 13). The set of vias may be divided into a first subset of vias and a second subset of vias, as discussed above. Some of the vias may be in both the first subset and second subset of vias, as discussed above.

The first SFP module includes a first set of pins configured to interface with the first subset of vias. The first set of pins has a first pin layout (e.g., pin layout 1550 illustrated in FIG. 15). The second SFP module includes a second set of pins configured to interface with the second subset of vias. The second set of pins has a second pin layout (e.g., pin layout 1560 illustrated in FIG. 15). At block 1810, the first SFP module is coupled to a first surface of the PCB. For example, the connector pins of the first SFP module may be press-fit into the first subset of vias of the PCB. At block 1815, the second SFP module is coupled to a second surface of the PCB. For example, the connector pins of the second SFP module may be press-fit into the second subset of vias of the PCB. As discussed above, at least one of the pins from the first SFP module and one of the pins from the second SFP module may interface with a common via. For example, a power pin from the first SFP module may be inserted into the same via as a power pin from the second SFP module. In another example, a ground pin from the first SFP module may be inserted into the same via as a ground pin from the second SFP module.

Detailed illustrative embodiments are disclosed herein. However, specific functional details disclosed herein are merely representative for purposes of describing embodiments. Embodiments may, however, be embodied in many alternate forms and should not be construed as limited to only the embodiments set forth herein. It should be appreciated that descriptions of direction and orientation are for convenience of interpretation, and the apparatus is not limited as to orientation with respect to gravity. In other words, the apparatus could be mounted upside down, right side up, diagonally, vertically, horizontally, etc., and the descriptions of direction and orientation are relative to portions of the apparatus itself, and not absolute.

It should be understood that although the terms first, second, etc., may be used herein to describe various steps or calculations, these steps or calculations should not be limited by these terms. These terms are only used to distinguish one step or calculation from another. For example, a first calculation could be termed a second calculation, and, similarly, a second step could be termed a first step, without departing from the scope of this disclosure. As used herein, the term “and/or” and the “/” symbol includes any and all combinations of one or more of the associated listed items.

As used herein, the singular forms “a”, “an” and “the” are intended to include the plural forms as well, unless the context clearly indicates otherwise. In addition, the term “set” includes one or more items within the set. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

With the above embodiments in mind, it should be understood that the embodiments might employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing. Any of the operations described herein that form part of the embodiments are useful machine operations. The embodiments also relate to a device or an apparatus for performing these operations. The apparatus can be specially constructed for the required purpose, or the apparatus can be a general-purpose computer selectively activated or configured by a computer program stored in the computer. In particular, various general-purpose machines can be used with computer programs written in accordance with the teachings herein, or it may be more convenient to construct a more specialized apparatus to perform the required operations.

A module, an application, a layer, an agent or other method-operable entity could be implemented as hardware, firmware, or a processor executing software, or combinations thereof. It should be appreciated that, where a software-based embodiment is disclosed herein, the software can be embodied in a physical machine such as a controller. For example, a controller could include a first module and a second module. A controller could be configured to perform various actions, e.g., of a method, an application, a layer or an agent.

The embodiments can also be embodied as computer readable code on a tangible non-transitory computer readable medium. The computer readable medium is any data storage device that can store data, which can be thereafter read by a computer system. Examples of the computer readable medium include hard drives, network attached storage (NAS), read-only memory, random-access memory, CD-ROMs, CD-Rs, CD-RWs, magnetic tapes, and other optical and non-optical data storage devices. The computer readable medium can also be distributed over a network coupled computer system so that the computer readable code is stored and executed in a distributed fashion. Embodiments described herein may be practiced with various computer system configurations including hand-held devices, tablets, microprocessor systems, microprocessor-based or programmable consumer electronics, minicomputers, mainframe computers and the like. The embodiments can also be practiced in distributed computing environments where tasks are performed by remote processing devices that are linked through a wire-based or wireless network.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

Various units, circuits, or other components may be described or claimed as “configured to” perform a task or tasks. In such contexts, the phrase “configured to” is used to connote structure by indicating that the units/circuits/components include structure (e.g., circuitry) that performs the task or tasks during operation. As such, the unit/circuit/component can be said to be configured to perform the task even when the specified unit/circuit/component is not currently operational (e.g., is not on). The units/circuits/components used with the “configured to” language include hardware—for example, circuits, memory storing program instructions executable to implement the operation, etc. Reciting that a unit/circuit/component is “configured to” perform one or more tasks is expressly intended not to invoke 35 U.S.C. 112, sixth paragraph, for that unit/circuit/component. Additionally, “configured to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks.

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

1. A network device, comprising:
a printed circuit board (PCB) comprising a plurality of vias through the PCB;
a first small format pluggable (SFP) module coupled to a first surface of the PCB, wherein: the first SFP module comprises a first set of pins configured to interface with a first subset of the plurality of vias; and
a second SFP module coupled to a second surface of the PCB, wherein the second SFP module comprises a second set of pins configured to interface with a second subset of the plurality of vias, and wherein:
a first pin of the first set of pins interfaces with plating in a first section of a first via in the plurality of vias, wherein the first pin interfaces the first via on a first side of the PCB;
a second pin of the second set of pins interfaces with plating in a first section of a second via in the plurality of vias, wherein the second pin interfaces the second via on a second side of the PCB;
the first via and the second via include three diameters;
a second section of the first via on the second side of the PCB does not include plating, wherein a pin from the second SFP module does not interface with the second section of the first via; and
a second section of the second via on the first side of the PCB does not include plating, wherein a pin from the first SFP module does not interface with the second section of the first via.

2. The network device of claim 1, wherein:
the first pin is configured to couple the first SFP module to a first data source that is coupled to the first via; and
the second pin is configured to couple the second SFP module to a second data source that is coupled to the second via.

3. (canceled)

4. (canceled)

5. The network device of claim 1, wherein the first pin and the second pin do not overlap in a horizontal dimension.

6. The network device of claim 1, wherein the first SFP module is identical to the second SFP module.

7. The network device of claim 6, wherein the second SFP module is oriented upside down with respect to the first SFP module.

8. The network device of claim 7, wherein a second pin layout of the second SFP module is a mirror image of a first pin layout of the first SFP module when the second SFP module is oriented upside down with respect to the first SFP module.

9. The network device of claim 8, wherein the first pin layout is identical to the second pin layout when the second SFP module is oriented in the same direction as the first SFP module.

10. The network device of claim 1, wherein:
the first SFP module comprises multiple stacked SFP modules; and
the second SFP module comprises multiple stacked SFP modules.

11. A network element, comprising:
a chassis configured to house a plurality of network devices;
a first network device housed within the chassis, the first network device comprising:
a printed circuit board (PCB) comprising a plurality of vias through the PCB;
a first small format pluggable (SFP) module coupled to a first surface of the PCB, wherein: the first SFP module comprises a first set of pins configured to interface with a first subset of the plurality of vias; and
a second SFP module coupled to a second surface of the PCB, wherein the second SFP module comprises a second set of pins configured to interface with a second subset of the plurality of vias, and wherein:
a first pin of the first set of pins interfaces with plating in a first section of a first via in the plurality of vias, wherein the first pin interfaces the first via on a first side of the PCB;
a second pin of the second set of pins interfaces with plating in a first section of a second via in the plurality of vias, wherein the second pin interfaces the second via on a second side of the PCB; and
the first via and the second via include three diameters;
a second section of the first via on the second side of the PCB does not include plating, wherein a pin from the second SFP module does not interface with the second section of the first via; and
a second section of the second via on the first side of the PCB does not include plating, wherein a pin from the first SFP module does not interface with the second section of the first via.

12. The network element of claim 1, wherein:
the first pin is configured to couple the first SFP module to a data source that is coupled to the first via; and
the second pin is configured to couple the second SFP module to a data source that is coupled to the second via.

13. (canceled)

14. The network element of claim 1, wherein the first pin and the second pin do not overlap in a horizontal dimension.

15. The network element of claim 1, wherein the first SFP module is identical to the second SFP module.

16. The network element of claim 15, wherein the second SFP module is oriented upside down with respect to the first SFP module.

17. The network element of claim 16, wherein the second pin layout is a mirror image of the first pin layout when the second SFP module is oriented upside down with respect to the first SFP module.

18. The network element of claim 15, wherein a second pin layout of the second SFP module is a mirror image of a first pin layout of the first SFP module when the second SFP module is oriented upside down with respect to the first SFP module.

19. (canceled)

20. A method of manufacturing a network device, the method comprising:
obtaining a printed circuit board (PCB) comprising a plurality of vias through the PCB;
obtaining a first small format pluggable (SFP) module, wherein:
the first SFP module comprises a first set of pins configured to interface with a first subset of the plurality of vias; and
obtaining a second SFP module, wherein:
the second SFP module comprises a second set of pins configured to interface with a second subset of the plurality of vias; and
coupling the first SFP module to a first surface of the PCB; and
coupling the second SFP module to a second surface of the PCB, wherein:
a first pin of the first set of pins interfaces with plating in a first section of a first via in the plurality of vias, wherein the first pin interfaces the first via on a first side of the PCB;
a second pin of the second set of pins interfaces with plating in a first section of a second via in the plurality of vias, wherein the second pin interfaces the second via on a second side of the PCB;
the first via and the second via include three diameters;
a second section of the first via on the second side of the PCB does not include plating, wherein a pin from the second SFP module does not interface with the second section of the first via; and
a second section of the second via on the first side of the PCB does not include plating, wherein a pin from the first SFP module does not interface with the second section of the first vias.

21. The network device of claim 1, further comprising:
a third via, wherein:
third pin of the first set of pins interfaces with the third via on the first side of the PCB;
a fourth pin of the second set of pins interfaces with the third via on the second side of the PCB.

22. The network device of claim 21, wherein:
the third pin is configured to couple the first SFP module to a power source or ground that is coupled to the third via; and
the fourth pin is configured to couple the second SFP module to the power source or the ground that is coupled to the third via.

23. The network device of claim 21, wherein:
the three diameters of the first via include:
a first diameter on the first side,
a second diameter on the second side, and
a third diameter in between the first section of the first via and the second section of the first via, and
the three diameters of the second via include:
a fourth diameter on the second side,
a fifth diameter on the first side, and
a sixth diameter in between the first section of the second via and the second section of the second via.

24. The network device of claim 1, wherein the three diameters of the first via and the second via are produced using three drillings.
